(19) United States
(12) Patent Application Publication
(10) Pub. No.: US 2025/0140714 A1
(43) Pub. Date: May 1, 2025

(54) SEMICONDUCTOR DEVICE AND METHOD OF MANUFACTURING THE SAME

(71) Applicant: SK hynix Inc., Icheon-si Gyeonggi-do (KR)

(72) Inventor: Yun Cheol HAN, Icheon-si Gyeonggi-do (KR)

(73) Assignee: SK hynix Inc., Icheon-si Gyeonggi-do (KR)

(21) Appl. No.: 18/610,452

(22) Filed: Mar. 20, 2024

(30) Foreign Application Priority Data
Nov. 1, 2023 (KR) 10-2023-0148866

(51) Int. Cl. H01L 23/58; H01L 25/065

(52) U.S. Cl. CPC H01L 23/585; H01L 25/0657; H01L 2225/06555

(57) ABSTRACT

Provided herein may be a semiconductor device and a method of manufacturing the same. A method of manufacturing a semiconductor device may include forming a stacked body in which first and second material layers are alternately stacked, the stacked body being formed in a chip area and a guard area, wherein the guard area is adjacent to the chip area, forming a plurality of first openings that pass through the stacked body of the guard area, the first openings being spaced apart from each other, forming a second opening from the plurality of first openings by expanding each of the plurality of first openings so that the plurality of first openings are coupled to each other, and forming a chip guard by filling the second opening with an insulating material.

### CROSS-REFERENCE TO RELATED APPLICATION

The present application claims priority under 35 U.S.C. § 119 (a) to Korean patent application number 10-2023-0148866, filed on Nov. 1, 2023, in the Korean Intellectual Property Office, which is incorporated herein by reference in its entirety.

### BACKGROUND

### 1. Technical Field

Various embodiments of the present disclosure generally relate to a semiconductor device and a method of manufacturing a semiconductor device, and more particularly to a semiconductor device including a chip guard adjacent to a chip area and a method of manufacturing the semiconductor device.

### 2. Related Art

Through a semiconductor integration process, a plurality of chip areas may be formed on a semiconductor substrate. The plurality of chip areas may be separated from each other by scribe lane areas. Since the semiconductor chip areas may be separated from each other through a cutting process, they may be manufactured as a plurality of semiconductor chips.

In order to protect an integrated circuit inside the chip area, a chip guard may be formed adjacent to the chip area. For example, the chip guard may be arranged to enclose the chip area. The chip guard may impede defect causing factors that may originate outside of the chip area and may be transmitted to the chip area.

### SUMMARY

An embodiment of the present disclosure may provide for a method of manufacturing a semiconductor device. The method may include forming a stacked body in which first and second material layers are alternately stacked, the stacked body being formed in a chip area and a guard area, wherein the guard area is adjacent to the chip area, forming a plurality of first openings that pass through the stacked body of the guard area, the first openings being spaced apart from each other, forming a second opening from the plurality of first openings by expanding each of the plurality of first openings so that the plurality of first openings are coupled to each other, and forming a chip guard by filling the second opening with an insulating material.

An embodiment of the present disclosure may provide for a semiconductor device. The semiconductor device may include a chip area and a chip guard adjacent to the chip area, and at least a portion of the chip guard may have widths that range from a first width to a second width, the second width being greater than the first width.

### BRIEF DESCRIPTION OF THE DRAWINGS

FIG. 1 is a view illustrating the structure of a semiconductor device according to an embodiment of the present disclosure.

FIG. 2 is a view illustrating the structure of a chip guard according to an embodiment of the present disclosure.

FIGS. 3A to 3C are views illustrating a method of manufacturing a chip guard according to an embodiment of the present disclosure.

FIGS. 4A to 4D are views illustrating a method of manufacturing a chip guard according to an embodiment of the present disclosure.

FIGS. 5A to 5F are views illustrating various layouts of chip guards according to an embodiment of the present disclosure.

FIG. 6 is a view illustrating the structure of a chip guard and a slit according to an embodiment of the present disclosure.

FIGS. 7A to 7E are views illustrating a method of simultaneously forming a chip guard and a slit according to an embodiment of the present disclosure.

FIG. 8 is a diagram illustrating a memory card system to which a memory device according to the present disclosure is applied.

FIG. 9 is a diagram illustrating a solid state drive (SSD) system to which a memory device according to the present disclosure is applied.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms and should not be construed as being limited to the embodiments described in the specification or application.

Hereinafter, various embodiments of the present disclosure will be described in detail with reference to the accompanying drawings in which embodiments of the present disclosure are illustrated so that those skilled in the art to which the present disclosure pertains can easily practice the technical spirit of the present disclosure.

Various embodiments of the present disclosure are directed to a semiconductor device and a method of manufacturing the semiconductor device, which can simplify the process of forming a chip guard and improve the performance of the chip guard.

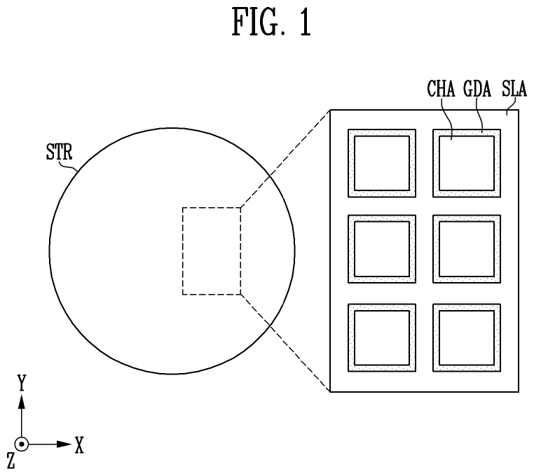

FIG. 1 is a view illustrating the structure of a semiconductor device according to an embodiment of the present disclosure.

The semiconductor device may include a structure STR. For example, the structure STR may be a substrate (e.g., silicon wafer, SiGe wafer, SOI wafer) or at least some of material patterns formed on the substrate.

Referring to FIG. 1, the structure STR may include chip areas CHA, guard areas GDA, and a scribe lane area SLA. For example, the structure STR may include the chip areas CHA, the guard areas GDA enclosing the chip areas CHA, respectively, and the scribe lane area SLA enclosing the guard areas GDA.

The chip areas CHA may be areas in which semiconductor chips are formed. Referring to FIG. 1, in a plan view, the chip areas CHA may be arranged on the structure STR, which is on an X-Y plane. Through a semiconductor integration process performed on the chip areas CHA, the semiconductor chips may be formed, respectively. The semiconductor chips formed in the plurality of chip areas CHA, respectively, within one structure STR, may be substantially identical. After the semiconductor integration process is completed on the substrate, the structure STR may be separated into the chip areas CHA, so that each of the chip areas CHA may be separated in the shape of the semiconductor chip.

Each of the guard areas GDA may be adjacent to each of the chip areas CHA. Each guard area GDA may enclose each chip area CHA. For example, the guard area GDA may be formed within a certain distance from a boundary of the chip area CHA. When a plane of the chip area CHA has a rectangular shape, a plane of the guard area GDA may have a rectangular ring shape that encloses the chip area CHA and contacts the periphery of the chip area CHA. In other words, an outer surface of the chip area CHA and an inner surface of the guard area GDA may contact each other.

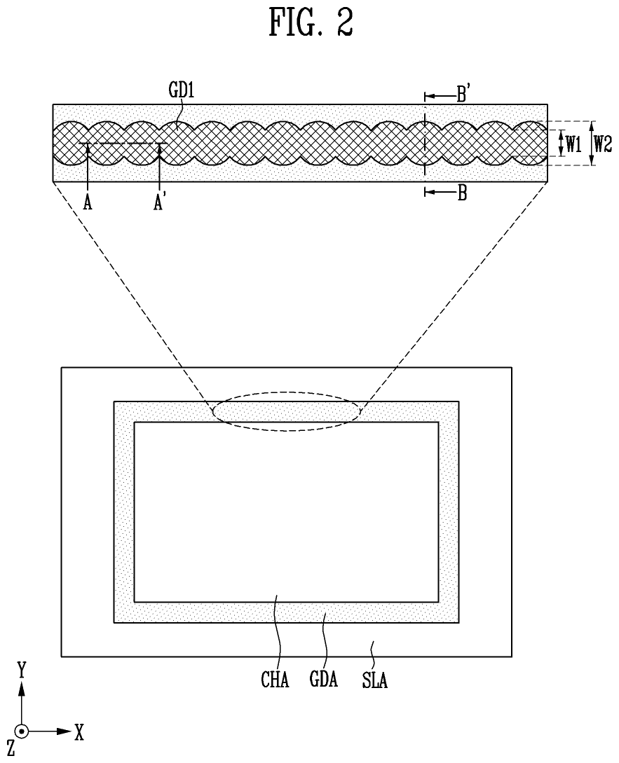

A chip guard may be formed in each of the guard areas GDA. The chip guard may prevent moisture or oxygen from penetrating into the chip area CHA. Further, the chip guard may reduce interference between dies during a packaging step, which is performed after the chip area CHA is separated into each semiconductor chip. The shape and manufacturing method of the chip guard formed in the guard area GDA will be described later with reference to FIGS. 2 to 7E.

The scribe lane area SLA may be located outside of the chip areas CHA and the guard areas GDA. For example, the scribe lane area SLA may be located between the chip areas CHA. After the semiconductor integration process has been completed, the scribe lane area SLA may be cut off during a dicing process that separates the semiconductor chips. Each of the chip areas CHA may be separated by cutting the structure STR along the scribe lane area SLA. Each separated semiconductor chip may include one chip area CHA and one guard area GDA, the one guard area GDA enclosing the chip area CHA. The process for cutting the structure STR may be implemented through a sawing process using a blade, a laser process using a laser, or a stealth dicing process. Electrical test patterns, process monitoring patterns, and alignment keys may be disposed in the scribe lane area SLA.

Although FIG. 1 illustrates six chip areas CHA for the convenience of description, the disclosure is not limited thereto. For example, the structure STR may include a varying number of chip areas CHA of 7 or more. In the present disclosure, the chip areas CHA, the guard areas GDA, and the scribe lane area SLA are separately described. However, this is for the convenience of description, and the chip areas CHA, the guard areas GDA, and the scribe lane area SLA may be continuously coupled to each other without being physically separated. For example, the positions of the chip areas CHA, guard areas GDA, and scribe lane area SLA on the substrate may vary.

FIG. 2 is a view illustrating the structure of the chip guard according to an embodiment of the present disclosure.

Referring to FIG. 2, the guard area GDA may be defined between the chip area CHA and the scribe lane area SLA. The guard area GDA may be positioned to be adjacent to the chip area CHA. The guard area GDA may be disposed to enclose the chip area CHA and may be in contact with the periphery of the chip area CHA. For example, the plane of the chip area CHA may have a rectangular shape, and the guard area GDA may extend along the boundary of the chip area CHA.

The chip guard may be formed in the guard area GDA. For example, the first chip guard GD1 may be located in the guard area GDA. The chip guard (e.g., first chip guard GD1) may be formed to be adjacent to the chip area CHA. The chip guard may or might not contact the chip area CHA. The chip guard (e.g., first chip guard GD1) may enclose the chip area CHA. For example, in the X direction of the chip area CHA (i.e., to the right and left of the chip area CHA), the chip guard (e.g., first chip guard GD1) may extend along the Y direction. Further, in the Y direction of the chip area CHA (i.e., above and below the chip area CHA), the chip guard (e.g., first chip guard GD1) may extend along the X direction. The chip guard (e.g., first chip guard GD1) may have a line-shaped plane. For example, a portion of the first chip guard GD1 located in the Y direction of the chip area CHA may have a line-shaped plane extending in the X direction.

At least a portion of the chip guard (e.g., first chip guard GD1) may have widths in which a first width W1 and a second width W2 are alternately repeated. The second width W2 may be greater than the first width W1. In the present disclosure, the width of the chip guard may represent the length of the chip guard in a direction perpendicular to the direction in which the chip guard extends on a plane. For example, a portion of the first chip guard GD1 in FIG. 2 may extend in the X direction, and the width of the first chip guard GD1 may refer to the length of the first chip guard GD1 in the Y direction.

The chip guard (e.g., first chip guard GD1) may have widths that range from the first width W1 to the second width W2. Range may be defined as including the end values of the first width W1 and the second width W2. For example, in FIG. 2, a minimum value among the widths of the first chip guard GD1 may be the first width W1, while a maximum value may be the second width W2. The first chip guard GD1 may have a width of any value between the first width W1 and the second width W2, in addition to the first width W1 and the second width W2.

The chip guard (e.g., first chip guard GD1) may have a curved boundary. The chip guard (e.g., first chip guard GD1) may include protrusions that protrude in a direction perpendicular to the direction in which the chip guard extends. For example, a portion of the first chip guard GD1 may extend in the X direction, and a portion of the first chip guard GD1 may have a curved boundary that is curved in the Y direction or in a direction opposite to the Y direction. The chip guard (e.g., first chip guard GD1) may have a shape in which multiple holes arranged along one direction (e.g., X direction) are expanded and coupled to each other.

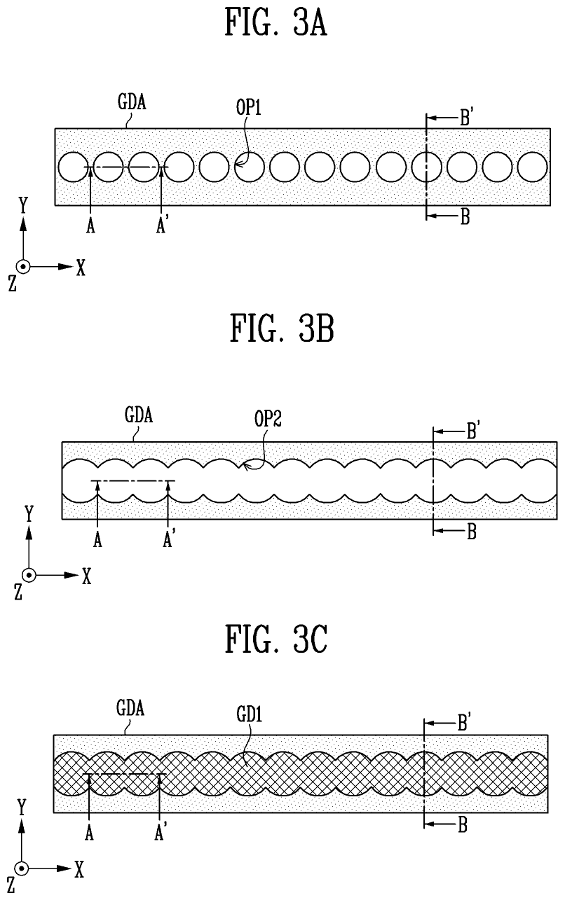

FIGS. 3A to 3C are views illustrating a method of manufacturing the chip guard according to an embodiment of the present disclosure.

Referring to FIG. 3A, first openings OP1 may be formed in the guard area GDA. The first openings OP1 may be arranged in a first direction. For example, the first openings OP1 may be arranged along the X direction and the Y direction to enclose the chip area CHA. FIG. 3A shows that the first openings OP1 are arranged along the X direction. However, since FIG. 3A illustrates only a portion of the guard area GDA, the first openings OP1 may be arranged along the Y direction to left or right of the chip area CHA in relation to the X direction in FIG. 2.

The first openings OP1 may be holes that are spaced apart from each other. The planar shape of each of the first openings OP1 may be circular or elliptical. Each of the first openings OP1 may be a hole that extends in the Z direction. The first openings OP1 may pass through at least a portion of the structure STR. In order to form the first openings OP1 at designated positions of the guard area GDA, an anisotropic dry etching process may be performed.

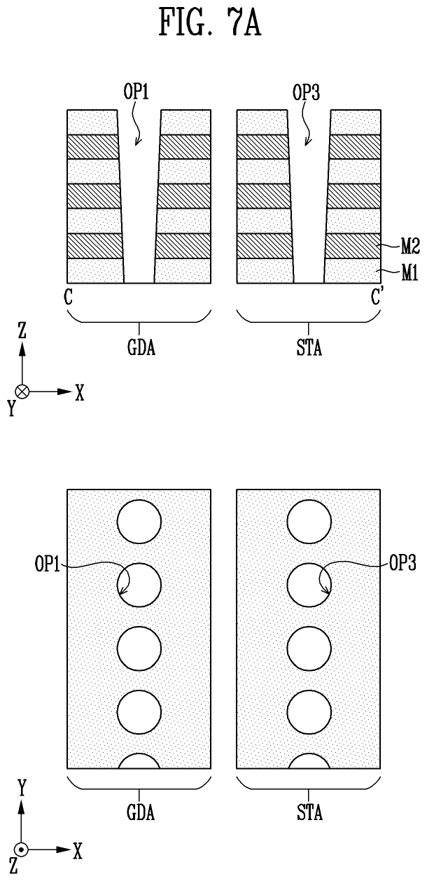

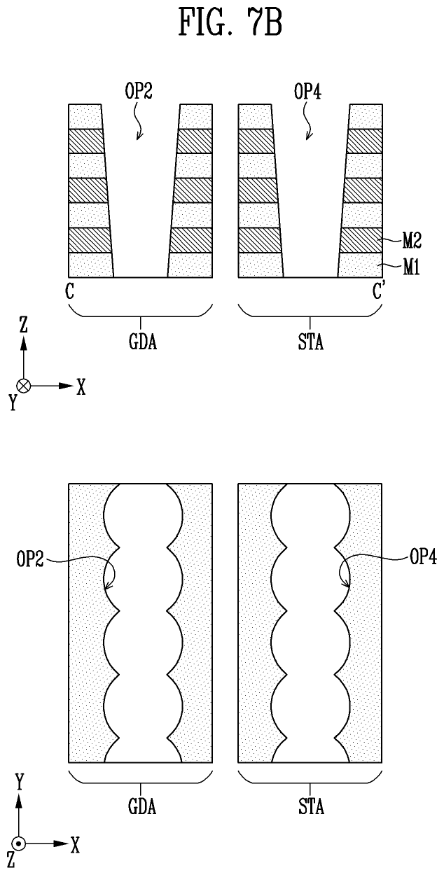

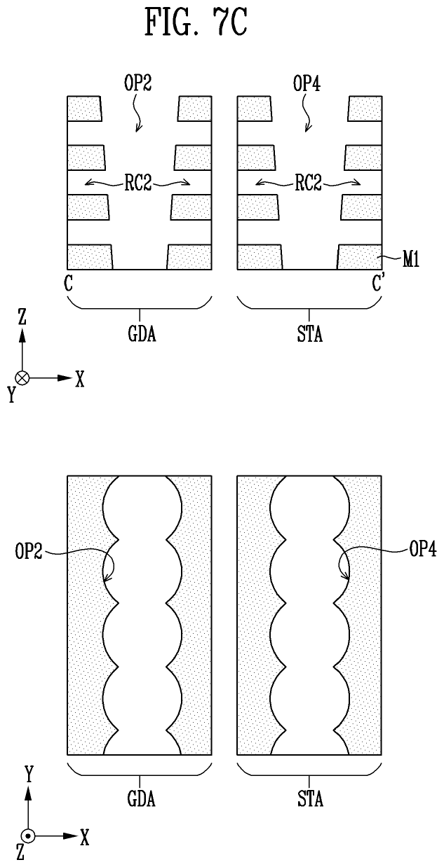

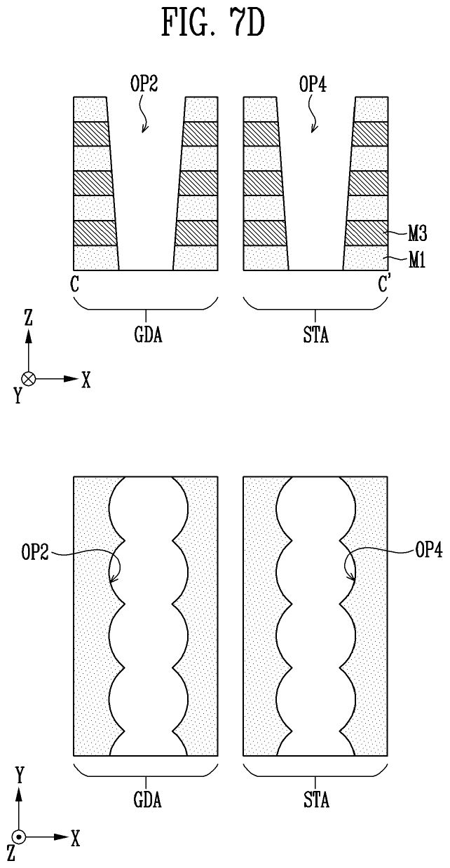

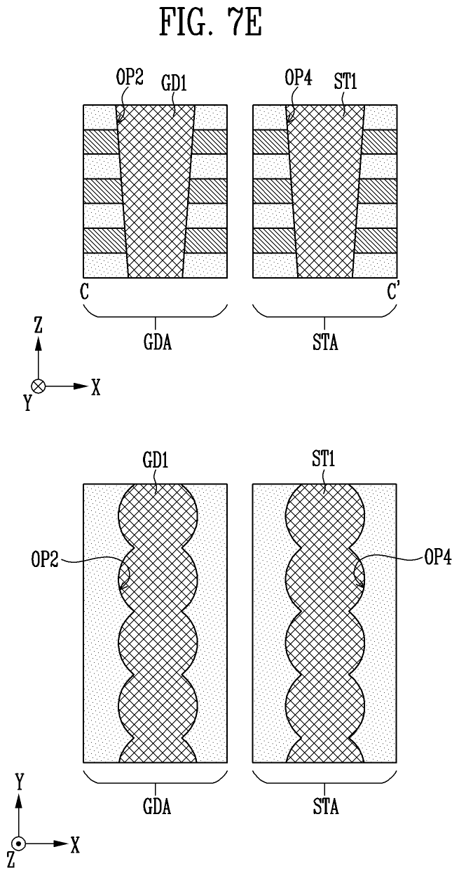

The first openings OP1 may be formed at the same time as when holes for forming a cell plug are formed inside the chip area CHA. Alternatively, the first openings OP1 may be formed at the same time as when holes for forming a slit are formed inside the chip area CHA. When a process of forming the first openings OP1 by etching the guard area GDA and a process of forming the holes for the cell plug or the holes for the slit by etching the chip area CHA are simultaneously performed, process cost and time required may be reduced because the processes for etching holes with a large aspect ratio are integrated. An embodiment in which the first openings OP1 are formed at the same time as when the holes for the slit are formed inside the chip area CHA will be described later with reference to FIGS. 7A to 7E.

Referring to FIG. 3B, each of the first openings OP1 may be expanded to form the second opening OP2. For example, the inner walls of the first openings OP1 may be etched through the first openings OP1. The expansion of each of the first openings OP1 may indicate an increase in the area of the first opening OP1 in a plan view. As each first opening OP1 is expanded, the first openings OP1 may be coupled to each other. The second opening OP2 may include the first openings OP1, each expanding and being coupled to each other. An isotropic wet etching process may be performed to expand the first openings OP1, thereby forming the second opening OP2. For example, a hard mask may be formed to expose the guard area GDA, and the isotropic wet etching process may be performed on portions of the guard area GDA exposed through the hard mask.

Referring to FIG. 3C, the chip guard (e.g., first chip guard GD1) may be formed in the second opening OP2. The chip guard (e.g., first chip guard GD1) may include an insulating material that fills the second opening OP2. For example, the second opening OP2 may be filled with a dielectric material having a low dielectric constant (low-k).

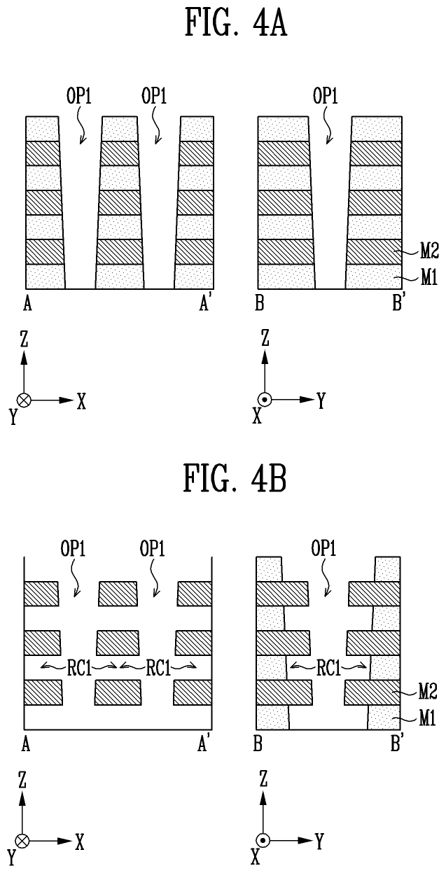

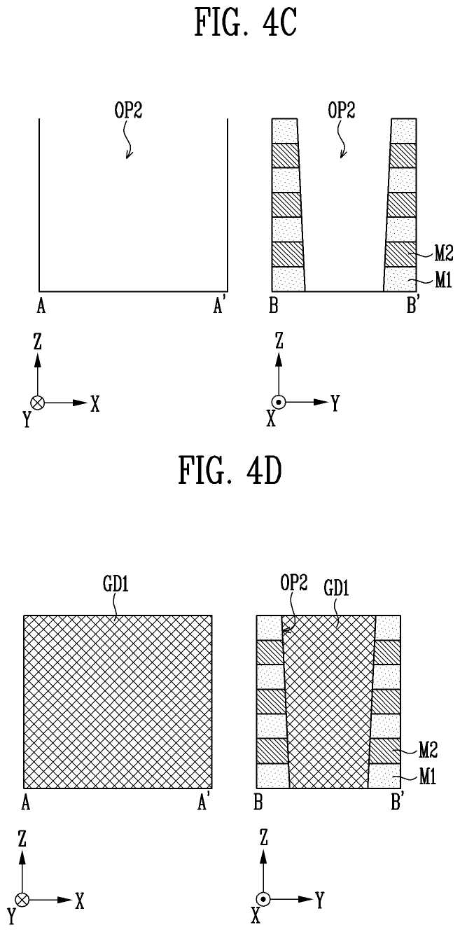

FIGS. 4A to 4D are views illustrating a method of manufacturing the chip guard according to an embodiment of the present disclosure. FIGS. 4A to 4D are sectional views taken along line A-A′ and line B-B′ of FIG. 2 during the different manufacturing steps.

Referring to FIG. 4A, a stacked body in which first material layers M1 and second material layers M2 are alternately stacked may be formed in the guard area GDA. For example, the first material layer M1 may be formed of an oxide layer (e.g., silicon oxide layer). The second material layer M2 may be formed of a material that may be selectively removed in a subsequent process. The second material layer M2 may be formed of material with a different etch selectivity from that of the first material layer M1. For example, the second material layer M2 may be formed of a nitride layer. Although FIG. 4A illustrates only the stacked body formed in the guard area GDA, the stacked body in which the first material layers M1 and the second material layers M2 are alternately stacked may also be formed in the chip area CHA.

The first openings OP1 may be formed in the guard area GDA. A portion of the stacked body of the guard area GDA may be etched to form the first openings OP1. The first openings OP1 may pass through the stacked body in which the first material layers M1 and the second material layers M2 are alternately stacked. Further, the first openings OP1 may be arranged to be spaced apart from each other along the X direction. The sectional view of FIG. 4A may correspond to the plan view of FIG. 3A.

Referring to FIG. 4B, at least a portion of the first material layers M1 may be removed through the first openings OP1. For example, HF or buffered oxide etchant (BOE) may be used to etch the first material layers M1. At least a portion of each of the first material layers M1 exposed through each of the first openings OP1 may be etched to form first recesses RC1. The first openings OP1 may be coupled to each other by the first recesses RC1.

Referring to FIG. 4C, at least a portion of the second material layers M2 may be removed through the first openings OP1 and the first recesses RC1. For example, phosphoric acid may be used to etch the second material layer M2. At least a portion of each of the second material layers M2 exposed through each of the first openings OP1 and each of the first recesses RC1 may be etched to form the second opening OP2. The second opening OP2 may have the shape of a line extending in the X direction. The sectional view of FIG. 4C may correspond to the plan view of FIG. 3B.

Referring to FIGS. 4B and 4C, the second opening OP2 may be formed by etching the stacked body exposed through each of the first openings OP1. A portion of the stacked body located between the first openings OP1 may be removed to couple the first openings OP1 to each other. For example, as described with reference to FIGS. 4B and 4C, after the first material layers M1 exposed through the first openings OP1 are etched, the second material layers M2 may be etched to form the second opening OP2. In another example, after the second material layers M2 exposed through the first openings OP1 are etched, the first material layers M1 may be etched to form the second opening OP2. In yet another example, the first material layers M1 and the second material layers M2 exposed through the first openings OP1 may be simultaneously etched to form the second opening OP2.

Referring to FIG. 4D, the second opening OP2 may be filled with an insulating material to form the chip guard (e.g., first chip guard GD1). For example, in order to fill the second opening OP2 with the insulating material, a thermal atomic layer deposition (ALD) or low pressure chemical vapor deposition (LPCVD) method may be used. The sectional view of FIG. 4D may correspond to the plan view of FIG. 3C.

The chip guard (e.g., first chip guard GD1) may prevent or reduce the inflow of harmful substances (e.g., H₂O, O₂) from the outside of the chip areas CHA. Further, the chip guard (e.g., first chip guard GD1) may reduce interference between semiconductor chips in a packaging process performed after the chip areas CHA are separated as the semiconductor chips. Since the chip guard (e.g., first chip guard GD1) includes the insulating material in the second opening OP2, it may electrically separate the chip areas CHA and may take a passivation role.

According to the present disclosure, since the boundary of the chip guard (e.g., first chip guard GD1) is a curved surface, crack propagation may be prevented or reduced when the scribe lane area SLA is cut to separate the chip areas CHA from each other.

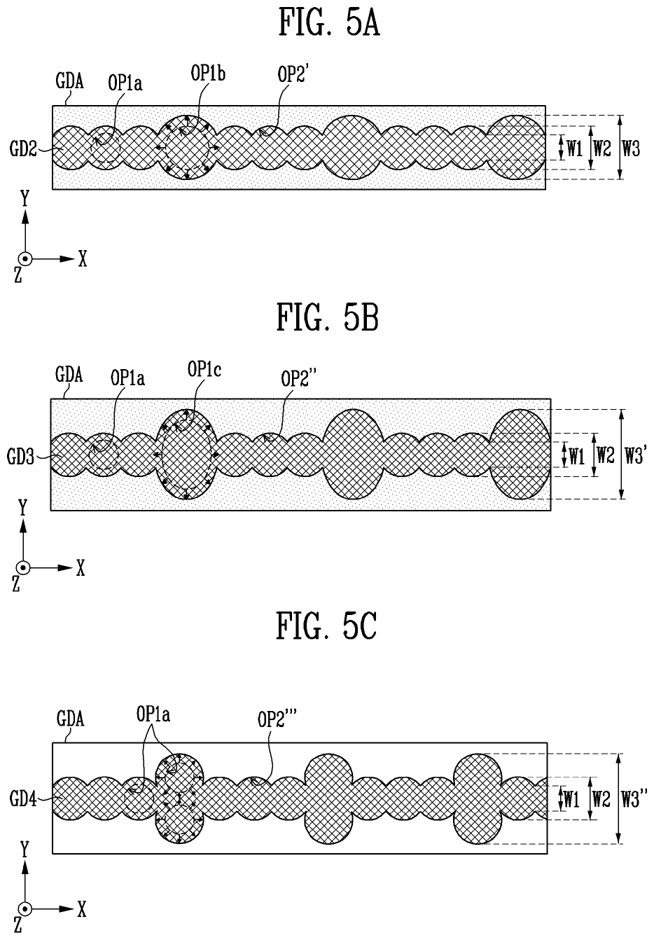

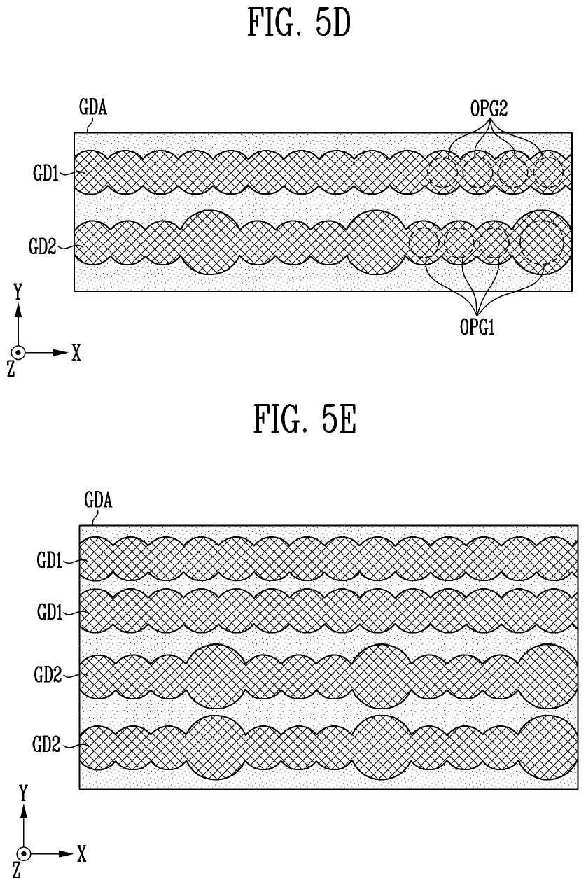

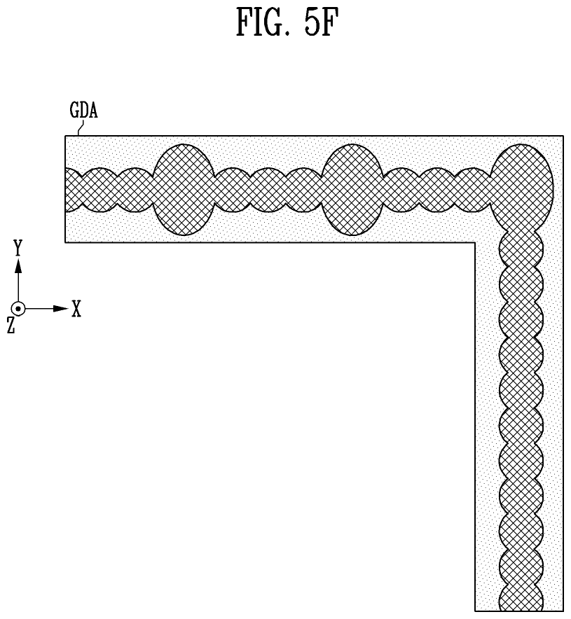

FIGS. 5A to 5F are views illustrating various layouts of chip guards according to an embodiment of the present disclosure.

Although FIG. 2, FIGS. 3A to 3C, and FIGS. 4A to 4D illustrate the first chip guard GD1 having widths that gradually alternate between the first width W1 and second width W2, the chip guard according to the present disclosure may be formed to have various layouts in addition to the layout of the first chip guard GD1. Similarly to FIG. 2, which illustrates only a portion of the first chip guard GD1 formed in a portion of the guard area GDA, FIGS. 5A to 5F may also be understood as illustrating only a portion of the chip guard formed in a portion of the guard area GDA. According to the present disclosure, in order to explain various shapes of the chip guard, they are referred separately to as first to fourth chip guards GD1 to GD4. However, the first to fourth chip guards GD1 to GD4 may be understood as corresponding to various examples of the chip guard.

Referring to FIG. 3A, the first chip guard GD1 may be formed through the first openings OP1 that have substantially the same planar shape and area and are arranged in one direction. However, the scope of the present disclosure is not limited to the first chip guard GD1. For example, a portion of the chip guard (e.g., the second chip guard GD2 of FIG. 5A, the third chip guard GD3 of FIG. 5B, and the fourth chip guard GD4 of FIG. 5C) may have a width that is greater than or equal to the first width W1 and less than or equal to the second width W2, and another portion may have a width that is greater than or equal to the first width W1 and less than or equal to a third width W3 (for FIG. 5A), W3′ (for FIG. 5B), or W3″ (for FIG. 5C). The third width W3, W3′, and W3″ may be greater than the second width W2. The information regarding the first chip guard GD1 described in FIG. 2, FIGS. 3A to 3C, and FIGS. 4A to 4D may also be applied to the second chip guard GD2 of FIG. 5A, the third chip guard GD3 of FIG. 5B, and the fourth chip guard GD4 of FIG. 5C, except that the first openings OP1 have the same planar shape and area and are arranged in one direction.

Referring to FIG. 5A, a portion of the second chip guard GD2 may have widths that range from the first width W1 to second width W2, and another portion may have widths that range from the first width W1 to third width W3. The second chip guard GD2 may be formed in the second opening OP2′ in which first openings OP1a and OP1b are expanded to be coupled. The first openings OP1a and OP1b may include first type openings OP1a and second type openings OP1b. In a plan view, the first type openings OP1a may have a first area, and the second type openings OP1b may have a second area that is larger than the first area. For example, the area of the opening may mean the cross-sectional area of the opening at any position on the Z-axis.

For example, a portion of the stacked body of the guard area GDA may be etched to form the first type openings OP1a and the second type openings OP1b. The first type openings OP1a and the second type openings OP1b may be arranged to be spaced apart from each other along the X direction. The plane of each of the first type openings OP1a may have a circular shape with a first size, while the plane of each of the second type openings OP1b may have a circular shape with a second size. The second size may be larger than the first size. The first type openings OP1a and the second type openings OP1b may have regularly repeating patterns. For example, a certain number (e.g., three) of first type openings OP1a may be arranged between the second type openings OP1b. A distance between consecutive second type openings OP1b may be 100 nm to 10 um.

Subsequently, the first openings OP1a and OP1b may be expanded to be coupled to each other. Therefore, the second opening OP2′ including the expanded first openings OP1a and OP1b may be formed. The second opening OP2′ may have widths that range from the first width W1 to the second width W2 in a first region corresponding to the first type openings OP1a. Further, the second opening OP2′ may have widths that range from the first width W1 to the third width W3 in a second region corresponding to the second type openings OP1b. The second chip guard GD2 may be formed as the second opening OP2′ is filled with the insulating material.

Referring to FIG. 5B, a portion of the third chip guard GD3 may have widths that range from the first width W1 to second width W2, and another portion may have widths that range from the first width W1 to third width W3′. The third chip guard GD3 may be formed in the second opening OP2″ in which first openings OP1a and OP1c are expanded to be coupled. The first openings OP1a and OP1c may include first type openings OP1a and second type openings OP1c. In a plan view, the first type openings OP1a may have a circular shape with a first area, and each of the second type openings OP1c may have an elliptical shape with a second area. Except for the cross-sectional shape of each of the second type openings OP1c, information regarding the second type openings OP1b, second opening OP2′, and third width W3 described with reference to FIG. 5A may also be applied to the second type openings OP1c, second opening OP2″, and third width W3′ of FIG. 5B.

Referring to FIG. 5C, a portion of the fourth chip guard GD4 may have widths that range from the first width W1 to second width W2, and another portion may have widths that range from the first width W1 to third width W3″. The fourth chip guard GD4 may be formed in the second opening OP2′″ in which first openings OP1a are expanded to be coupled. In a plan view, the first openings OP1a may have a circular shape with a first area.

Unlike the second type openings OP1b and OP1c formed between the first type openings OP1a when the second chip guard GD2 and the third chip guard GD3 are formed, the second type openings OP1b and OP1c might not be formed when the fourth chip guard GD4 is formed. For example, the fourth chip guard GD4 may be formed using the first openings OP1a that have the same cross-sectional shape and cross-sectional area. Instead of forming the second type openings OP1b and OP1c, multiple first openings OP1a may be formed in a direction perpendicular to a direction in which the fourth chip guard GD4 extends. For example, referring to FIG. 5C, a pair of the first openings OP1a may be formed side by side in the Y direction, between the first openings OP1a arranged along the X direction.

Except for the fact that the second type openings OP1b are not formed and positions in which some of the first type openings OP1a are arranged are different, information regarding the first opening OP1a, second opening OP2′, and third width W3 described with reference to FIG. 5A may also be applied to the first opening OP1a, second opening OP2″, and third width W3″ of FIG. 5C.

As illustrated in FIGS. 5A to 5C, compared to the first chip guard GD1 illustrated in FIG. 2, the second to fourth chip guards GD2 to GD4 may have widths corresponding to various values. For example, while the first chip guard GD1 may have widths that range from the first width W1 to the second width W2, the second chip guard GD2 may have widths that range from the first width W1 to the third width W3. Further, compared to the planar shape of the first chip guard GD1, the second to fourth chip guards GD2 to GD4 may have a planar shape in which a repeating pattern is longer in length. For example, a period in which the shape of the first chip guard GD1 is repeated may correspond to a distance between centers of neighboring first openings OP1 among the first openings OP1. On the other hand, a period in which the shape of the second chip guard GD2 is repeated may correspond to a distance between centers of consecutive second type openings OP1b that are adjacent to each other with the first type openings OP1a therebetween, among the second type openings OP1b.

When the first openings OP1a, OP1b, and OP1c are formed to have various shapes or areas in a plan view, the performance of the chip guard (e.g., second to fourth chip guards GD2 to GD4) may be improved. For example, as the pattern of the width of the chip guard (e.g., second to fourth chip guards GD2 to GD4) becomes more complex, the chip guard can more effectively prevent cracks from propagating from the outside of the chip area CHA.

Referring to FIG. 5D, at least two chip guards (e.g., first to fourth chip guards GD1 to GD4) may be disposed around one chip area CHA. At least two chip guards (e.g., first to fourth chip guards GD1 to GD4) may enclose one chip area CHA. For example, the second chip guard GD2 may be disposed to enclose the chip area CHA, and the first chip guard GD1 may be disposed to enclose the chip area CHA and the second chip guard GD2.

For example, a first opening group OPG1 including openings arranged along the X direction may be formed in the guard area GDA. Further, a second opening group OPG2 arranged around the first opening group OPG1 may be formed in the guard area GDA. The openings of the first opening group OPG1 may be spaced apart from openings of the second opening group OPG2. The openings included in the first opening group OPG1 may be coupled to each other, and the openings included in the second opening group OPG2 may be coupled to each other. The second chip guard GD2 of FIG. 5D may be formed in a region in which the openings of the first opening group OPG1 are coupled to each other. Further, the first chip guard GD1 of FIG. 5D may be formed in a region in which the openings of the second opening group OPG2 are coupled to each other.

When two chip guards enclose one chip area CHA, the two chip guards may be of the same type (e.g., at least two first chip guards GD1) or of different types (e.g., first chip guard GD1 and second chip guard GD2). Further, when more than three chip guards enclose one chip area CHA, two or more chip guards may be of the same type, and others may be chip guards of different types. For example, referring to FIG. 5E, two first chip guards GD1 and two second chip guards GD2 may be located around one chip area CHA.

Referring to FIGS. 5D and 5E, the chip guards (e.g., first to fourth chip guards GD1 to GD4) may be formed to enclose any one chip area CHA at least twice. When the chip area CHA is enclosed by the chip guard (e.g., first to fourth chip guards GD1 to GD4) at least twice compared to a case in which it is enclosed only once, the chip guard can more effectively protect the chip area CHA.

Further, according to the present disclosure, after the hole-shaped first openings OP1, OP1a, OP1b, and OP1c are formed, the first openings OP1, OP1a, OP1b, and OP1c may be expanded to form line-shaped second openings OP2, OP2′, OP2″, and OP2′″. Therefore, since it is easy to change the method of arranging the hole-shaped first openings OP1, OP1a, OP1b, and OP1c, it may be easy to adjust the number or shape of the chip guards during the design process of the semiconductor device.

Referring to FIG. 5F, any one chip guard may have different shapes depending on its position. For example, in the guard area GDA located above and below the chip area CHA, the chip guard may have a shape similar to that of the third chip guard GD3 of FIG. 5B. Further, in the guard area GDA located to the left and right of the chip area CHA, the chip guard may have a shape similar to that of the first chip guard GD1 of FIG. 2.

The layouts of the chip guards, illustrated in FIGS. 5A to 5F, correspond to some of the embodiments embraced in the scope of the present disclosure, and other embodiments are possible. For example, in the plan view, the first openings OP1, OP1a, OP1b, and OP1c may have various shapes, such as a circle, an ellipse, or a square with rounded corners. Alternatively, there may be at least three types of first openings OP1, OP1a, OP1b, and OP1c corresponding to one chip guard. That is, as long as the chip guard is formed by forming the first openings that are spaced apart from each other and then forming the second opening through the expansion and coupling of the first openings, it may fall within the purview of the present disclosure.

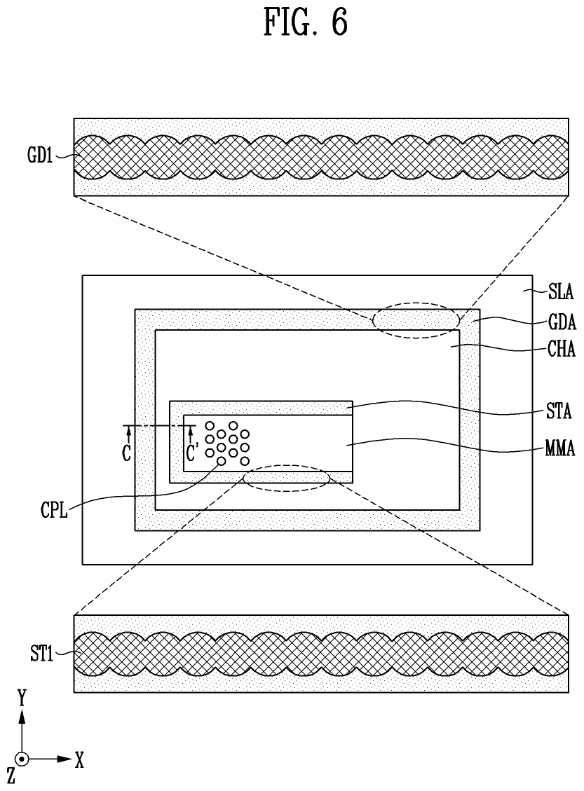

FIG. 6 is a view illustrating the structure of the chip guard and the slit according to an embodiment of the present disclosure. Among configurations illustrated in FIG. 6, the configuration illustrated in FIG. 2 may be briefly described or omitted.

Referring to FIG. 6, the chip area CHA may include a memory area MMA. The memory area MMA may be formed inside the chip area CHA. 3D NAND memory cells may be formed in the memory area MMA. A slit area STA may be located around the memory area MMA. The slit area STA may be disposed to be adjacent to the memory area MMA. For example, the slit area STA may enclose at least a portion of corners of the memory area MMA.

Cell plugs CPL may be located in the memory area MMA. The cell plugs CPL may be arranged in the memory area MMA along the X direction and the Y direction. Each of the cell plugs CPL may extend along the Z direction. Each of the cell plugs CPL may penetrate at least a portion of the structure STR.

A slit (e.g., first slit ST1) may be located in the slit area STA. The slit (e.g., first slit ST1) may include an insulating material. The slit (e.g., first slit ST1) may divide the memory area MMA from other memory areas. For example, word lines of the memory area MMA may be electrically separated from word lines of another memory area by the slit (e.g., first slit ST1). Although FIG. 6 illustrates only a portion of the shape of the slit (e.g., first slit ST1), it is understood that the slit (e.g., first slit ST1) also extends along a direction in which the slit area STA extends.

The slit (e.g., first slit ST1) formed in the slit area STA may have a shape similar to that of the chip guard (e.g., first chip guard GD1) formed in the guard area GDA. For example, the slit (e.g., first slit ST1) may have a planar shape similar to that of the first chip guard GD1. In another example, the slit may have a planar shape similar to that of any one of the chip guards illustrated in FIGS. 5A to 5F. Since the chip guard (e.g., first chip guard GD1) is formed in the guard area GDA at the same time as the slit (e.g., first slit ST1) is being formed in the slit area STA, the shapes of the slit (e.g., first slit ST1) and the chip guard (e.g., first chip guard GD1) may be similar. The method of forming the chip guard (e.g., first chip guard GD1) and the slit (e.g., first slit ST1) will be described later with reference to FIGS. 7A to 7E.

FIGS. 7A to 7E are views illustrating a method of simultaneously forming a chip guard and a slit according to an embodiment of the present disclosure. FIGS. 7A to 7E are sectional views taken along line C-C′ of FIG. 6.

Referring to FIG. 7A, stacked bodies in which first material layers M1 and second material layers M2 are alternately stacked may be formed in the guard area GDA and the slit area STA. The first and second material layers M1 and M2 may be identical to the first and second material layers M1 and M2 described with reference to FIG. 4A.

The first openings OP1 may be formed in the guard area GDA, and third openings OP3 may be formed in the slit area STA. A portion of the stacked body of the guard area GDA may be etched to form the first openings OP1. Further, a portion of the stacked body of the slit area STA may be etched to form the third openings OP3. The process of etching the stacked body of the guard area GDA and the process of etching the slit area STA of the chip area CHA may be simultaneously performed. In order to form the first openings OP1 and the third openings OP3 at designated positions of the guard area GDA and the slit area STA, the anisotropic dry etching process may be performed.

Each of the first openings OP1 and the third openings OP3 may pass through the stacked bodies in which the first material layers M1 and the second material layers M2 are alternately stacked. Further, the first openings OP1 and the third openings OP3 may be arranged along the X direction or along the Y direction. The first openings OP1 may be arranged to be spaced apart from each other. The third openings OP3 may be arranged to be spaced apart from each other. The first openings OP1 and the third openings OP3 may be arranged to be spaced apart from each other. The planar areas of the first openings OP1 and the planar areas of the third openings OP3 (i.e., area of the opening in a plan view) may be variously formed. For example, the planar areas of the first openings OP1 may be formed to be larger than the planar areas of the third openings OP3. In another example, the first openings OP1 and the third openings OP3 may be formed to have substantially the same planar area.

Referring to FIG. 7B, the first openings OP1 may be expanded to form the second opening OP2, and the third openings OP3 may be expanded to form the fourth opening OP4. A process in which the first openings OP1 are expanded to be coupled to each other and a process in which the third openings OP3 are expanded to be coupled to each other may be simultaneously performed. For example, when the inner walls of the first openings OP1 are etched through the first openings OP1, the inner walls of the third openings OP3 may be simultaneously etched through the third openings OP3. As the third openings OP3 are expanded, the third openings OP3 may be coupled to each other. The portion of the fourth opening OP4 at C-C′ may have the shape of a line extending in the Y direction. The fourth opening OP4 may include the third openings OP3 that are expanded and coupled to each other. The isotropic wet etching process may be performed to form the second opening OP2 by expanding and coupling the first openings OP1 and to form the fourth opening OP4 by expanding and coupling the third openings OP3. For example, the hard mask may be formed to expose the guard area GDA and the slit area STA, and the isotropic wet etching process may be performed on portions of the guard area GDA that are exposed through the hard mask and portions of the slit area STA that are exposed through the hard mask.

Referring to FIG. 7C, the second material layers M2 may be removed through the second opening OP2 and the fourth opening OP4. The second material layers M2 that are exposed through the second opening OP2 and the fourth opening OP4 may be etched. Since the second material layers M2 are formed of material with an etch selectivity different from that of the first material layers M1, the second material layers M2 may be selectively removed. The isotropic wet etching process may be performed to selectively remove the second material layers M2.

As the second material layers M2 are removed, second recesses RC2 may be formed between the first material layers M1. The second opening OP2 and the fourth opening OP4 may be used as a passageway through which an etchant for removing the second material layers M2 is introduced. Further, the second opening OP2 and the fourth opening OP4 may be used as a passageway through which the etched second material layers M2 are removed.

Referring to FIG. 7D, the second recesses RC2 may be filled with third material layers M3. The third material layers M3 may fill the second recesses RC2 through the second opening OP2 and the fourth opening OP4. The second opening OP2 and the fourth opening OP4 may be used as a passageway through which the third material layers M3 are introduced. The third material layers M3 formed to be adjacent to the second opening OP2 and the third material layers M3 formed to be adjacent to the fourth opening OP4 may include the same material. The third material layers M3 may include a conductive layer. For example, the third material layers M3 may be formed of at least one of tungsten (W), cobalt (Co), nickel (Ni), molybdenum (Mo), silicon (Si), or poly-silicon (poly-Si). At least some of the third material layers M3 may be used as a gate electrode. For example, the third material layers M3 formed in the memory area MMA may be used as a word line or a select line.

Referring to FIG. 7E, the chip guard (e.g., first chip guard GD1) may be formed in the second opening OP2, and the slit (e.g., first slit ST1) may be formed in the fourth opening OP4. The interior of the second opening OP2 and the interior of the fourth opening OP4 may be simultaneously filled with insulating material. The chip guard (e.g., first chip guard GD1) and the slit (e.g., first slit ST1) may be simultaneously formed. Therefore, the chip guard (e.g., first chip guard GD1) and the slit (e.g., first slit ST1) may include the same material.

Referring to FIGS. 7A to 7E, since memory areas MMA are separated from each other and the gate electrode (e.g., third material layers M3) is formed during the process of forming the chip guard (e.g., first chip guard GD1), the manufacturing process of the semiconductor device can be simplified. Therefore, cost and time required to manufacture the semiconductor device including the chip guard (e.g., first chip guard GD1) and the slit (e.g., first slit ST1) according to the present disclosure can be reduced.

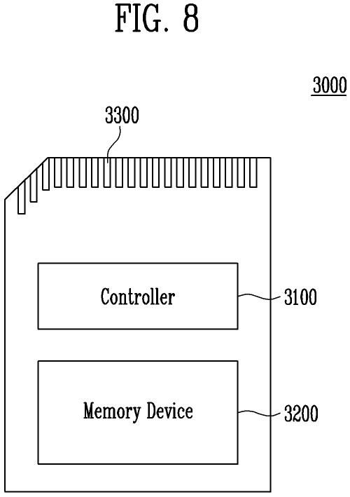

FIG. 8 is a diagram illustrating a memory card system to which a memory device according to the present disclosure is applied.

Referring to FIG. 8, a memory card system 3000 may include a controller 3100, a memory device 3200, and a connector 3300.

The controller 3100 may be coupled to the memory device 3200. The controller 3100 may access the memory device 3200. For example, the controller 3100 may control a program operation, a read operation, or an erase operation of the memory device 3200 or may control background operations of the memory device 3200. The controller 3100 may provide an interface between the memory device 3200 and a host. The controller 3100 may run firmware for controlling the memory device 3200. In an embodiment, the controller 3100 may include components, such as a random access memory (RAM), a processing unit, a host interface, a memory interface, and an error correction circuit.

The controller 3100 may communicate with an external device through the connector 3300. The controller 3100 may communicate with an external device (e.g., a host) based on a specific communication standard. For example, the controller 3100 may communicate with the external device through at least one of the following communication standards: universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, nonvolatile memory express (NVMe), and the like. For example, the connector 3300 may be defined by at least one of the above-described various communication standards.

The memory device 3200 may include a plurality of memory cells.

The controller 3100 and the memory device 3200 may be integrated into a single semiconductor device to form a memory card. For example, the controller 3100 and the memory device 3200 may be integrated into a single semiconductor device and may then form a memory card, such as a PC card (personal computer memory card international association: PCMCIA), a compact flash card (CF), a smart media card (SM or SMC), a memory stick, a multimedia card (MMC, RS-MMC, MMCmicro or eMMC), a SD card (SD, miniSD, microSD, or SDHC), or universal flash storage (UFS).

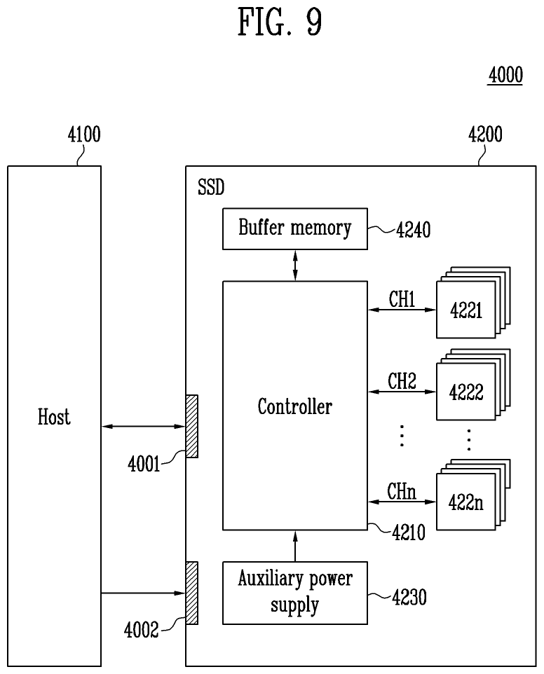

FIG. 9 is a diagram illustrating a solid state drive (SSD) system to which a memory device according to the present disclosure is applied.

Referring to FIG. 9, an SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. In an embodiment, the signal may indicate signals based on the interfaces of the host 4100 and the SSD 4200. For example, the signal may be a signal defined by at least one of the following interfaces: universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, nonvolatile memory express (NVMe), and the like.

Each of the plurality of memory devices 4221 to 422n may include a plurality of memory cells that store data. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100 and may be charged. The auxiliary power supply 4230 may provide the supply voltage of the SSD 4200 when the supply of power from the host 4100 is not smoothly performed. For example, the auxiliary power supply 4230 may be located inside the SSD 4200 or located outside the SSD 4200. For example, the auxiliary power supply 4230 may be located on a main board and may also provide auxiliary power to the SSD 4200.

The buffer memory 4240 may function as a buffer memory of the SSD 4200. For example, the buffer memory 4240 may temporarily store data received from the host 4100 or data received from the plurality of memory devices 4221 to 422n or may temporarily store metadata (e.g., mapping tables) of the memory devices 4221 to 422n. The buffer memory 4240 may include volatile memories, such as a DRAM, SDRAM, DDR SDRAM, and LPDDR SDRAM, or nonvolatile memories, such as an FRAM, ReRAM, STT-MRAM, and PRAM.

According to the present disclosure, a process of forming a chip guard is improved, thus simplifying the process of forming the chip guard and improving the performance of the chip guard.

What is claimed is:

1. A method of manufacturing a semiconductor device, comprising:
forming a stacked body in which first and second material layers are alternately stacked, the stacked body being formed in a chip area and a guard area, wherein the guard area is adjacent to the chip area;
forming a plurality of first openings that pass through the stacked body of the guard area, the first openings being spaced apart from each other;
forming a second opening from the plurality of first openings by expanding each of the plurality of first openings so that the plurality of first openings are coupled to each other; and
forming a chip guard by filling the second opening with an insulating material.

2. The method according to claim 1,
wherein the first openings are formed in a shape of holes spaced apart from each other along a first direction, and
wherein the second opening is formed in a shape of a line extending in the first direction.

3. The method according to claim 1, wherein the guard area encloses the chip area, and
wherein the forming of the plurality of first openings comprises etching a portion of the stacked body of the guard area that encloses the chip area.

4. The method according to claim 1, wherein the forming of the second opening comprises etching the stacked body exposed through each of the first openings.

5. The method according to claim 4, wherein the etching of the stacked body comprises:
forming a plurality of first recesses by removing at least a portion of each of the first material layers exposed through each of the plurality of first openings; and
forming the second opening by removing at least a portion of each of the second material layers exposed through each of the plurality of first openings and each of the plurality of first recesses.

6. The method according to claim 1, wherein the forming of the second opening comprises coupling the plurality of first openings to each other by removing a portion of the stacked body located between adjacent first openings, among the plurality of first openings, in the stacked body.

7. The method according to claim 1, wherein the forming of the second opening comprises etching a portion of the stacked body so that the second opening has widths that range from a first width to a second width, the second width being greater than the first width.

8. The method according to claim 1, wherein the forming of the plurality of first openings comprises:
forming a plurality of first type openings having a first area in a plan view; and
forming a plurality of second type openings having a second area in the plan view, the second area being greater than the first area.

9. The method according to claim 8, wherein the forming of the plurality of first type openings and the plurality of second type openings comprises etching a portion of the stacked body to have a pattern including a combination of the plurality of first type openings and at least one second type opening that are regularly repeated.

10. The method according to claim 8, wherein the forming of the first type openings comprises forming the first type openings having a circular shape of the first size in the plan view.

11. The method according to claim 8, wherein the forming of the second type openings comprises forming the second type openings having a circular or elliptical shape of the second size in the plan view.

12. The method according to claim 8, wherein the forming of the second type openings comprises forming the second opening that has widths that range from a first width to a second width in a first region corresponding to the plurality of first type openings and has widths that range from the first width to a third width in a second region corresponding to the plurality of second type openings, and
wherein the second width is greater than the first width and the third width is greater than the second width.

13. The method according to claim 1, wherein the forming of the plurality of first openings comprises forming a first opening group including a plurality of openings arranged along a first direction in the guard area, and a second opening group including a plurality of openings arranged along the first direction and spaced apart in a second direction from the plurality of openings of the first opening group.

14. The method according to claim 13, wherein the forming of the second opening comprises:
coupling the plurality of openings included in the first opening group to each other; and
coupling the plurality of openings included in the second opening group to each other.

15. The method according to claim 1, wherein the forming of the plurality of first openings is performed at the same time as forming a plurality of third openings that pass through the stacked body, the plurality of first openings being spaced apart from the plurality of third openings in the chip area.

16. The method according to claim 15, wherein the forming of the second opening is performed at the same time as forming a fourth opening from the plurality of third openings by expanding each of the plurality of third openings so that the plurality of third openings are coupled to each other in the chip area.

17. The method according to claim 16, further comprising:
after forming the second opening and the fourth opening,
forming a plurality of second recesses by removing the plurality of second material layers exposed through the second opening and the fourth opening; and
filling the plurality of second recesses with a plurality of third material layers.

18. The method according to claim 17, wherein the forming of the chip guard is performed at the same time as forming a slit by filling the fourth opening with the insulating material.

19. A semiconductor device, comprising:
a chip area; and
a chip guard adjacent to the chip area,
wherein at least a portion of the chip guard has widths that range from a first width to a second width, the second width being greater than the first width.

20. The semiconductor device according to claim 19, wherein the chip guard's width gradually alternates between the first width and the second width, and
wherein the chip guard encloses the chip area.

21. The semiconductor device according to claim 19,
wherein a first region of the chip guard has widths that range from the first width to the second width, and
wherein a second region of the chip guard has widths that range from the first width to a third width, the third width being greater than the second width.

22. The semiconductor device according to claim 19, wherein, in a plan view, at least a portion of the chip guard is line-shaped extending in a first direction and has a curved boundary that curves in a second direction, the second direction intersecting the first direction and a direction opposite to the second direction.

23. The semiconductor device according to claim 19, wherein at least a portion of the chip guard has a shape in which holes arranged along the first direction are expanded and coupled to each other.
